(19) United States
(12) Patent Application Publication
(10) Pub. No.: US 2014/0092557 A1
(43) Pub. Date: Apr. 3, 2014

(54) ELECTRONIC DEVICE WITH HEAT DISSIPATING MODULE

(71) Applicant: HON HAI PRECISION INDUSTRY CO., LTD., New Taipei (TW)

(72) Inventor: SHUN-SIANG TU, New Taipei (TW)

(21) Appl. No.: 13/915,794

(22) Filed: Jun. 12, 2013

(30) Foreign Application Priority Data
Sep. 28, 2012 (TW) 101136116

(51) Int. Cl. H05K 7/20

(52) U.S. Cl. CPC H05K 7/20154
USPC 361/697; 165/80.3

(57) ABSTRACT

An electronic device includes a bottom enclosure and a heat dissipating module. The heat dissipating module includes an installation box, a fan received in the installation box, and a plurality of fins secured to the installation box and closed to the fan. The installation box defines a cutout located between the fan and the plurality of fins. Airflow generated by the fan is guided along a first direction by the plurality of fins to dissipate heat generated by a heat generating component, and along a second direction through the cutout to dissipate heat generated by the bottom enclosure; the second direction is substantially perpendicular to the first direction. The heat dissipating module dissipates heat for the heat generating component and the bottom enclosure simultaneously.

### BACKGROUND

1. Technical Field

The present disclosure relates to electronic devices, and more particularly to an electronic device with a heat dissipating module.

2. Description of Related Art

As notebook computers become thinner from technology development. A plurality of fins is used in the notebook for dissipating heat generated by electronic component, such as Central Processing Unit (CPU). The plurality of fins abuts an enclosure of the notebook, which may increase temperature of the enclosure. To decrease the temperature, on the one hand, the height of the plurality of fins are reduced, which may reduce an area of each of plurality of fins to influence radiation efficiency of the electronic component, and on another hand, coppers or graphite sheets are pasted on the enclosure to dissipate heat of the enclosure, that may increase costs. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device in accordance with an embodiment.

FIG. 2 is an enlarged view of a circled portion II of FIG. 1.

FIG. 3 is similar to FIG. 1, but a baffle piece being secured to an installation box.

FIG. 4 is an assembled view of the electronic device of FIG. 1.

FIG. 5 is a cross-sectional view of the electronic device of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

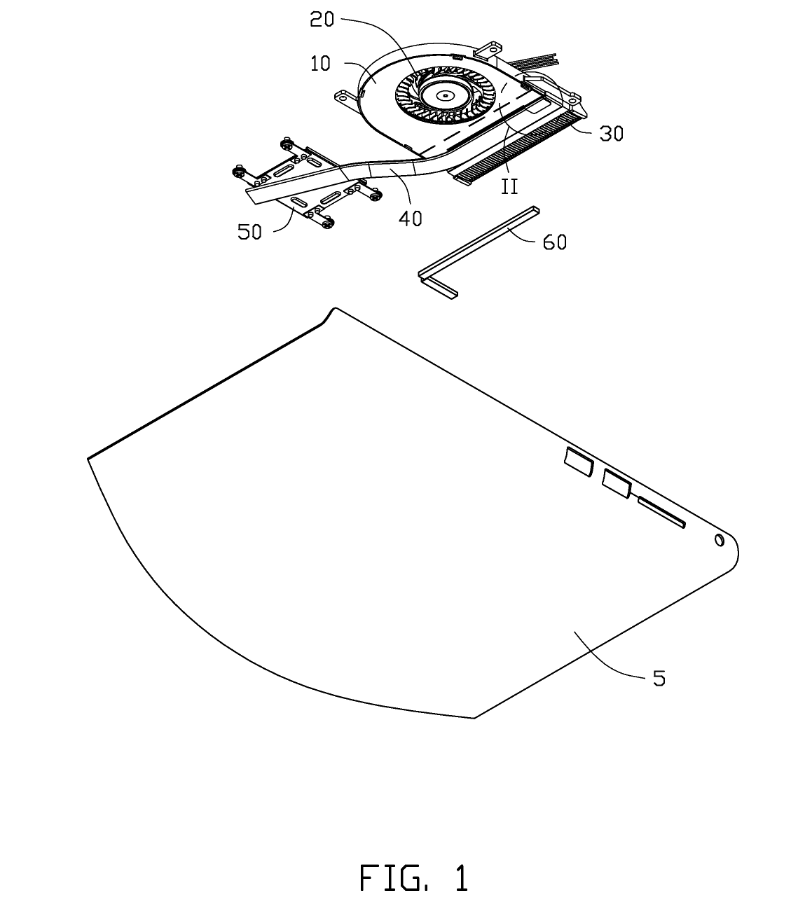

FIGS. 1-3 illustrate an electronic device in accordance with an embodiment. The electronic device includes a bottom enclosure 5 and a heat dissipating module 80 attached to the bottom enclosure 5. The electronic device may be a notebook computer, for example. The electronic device further includes a main body (not shown) on which a plurality of heat generating components is located.

The heat dissipating module 80 includes an installation box 10 attached to the bottom enclosure 5, a fan 20 received in the installation box 10, a plurality of fins 30, a heat pipe 40, a heat sink 50 attached to the heat pipe 40, and a baffle piece 60.

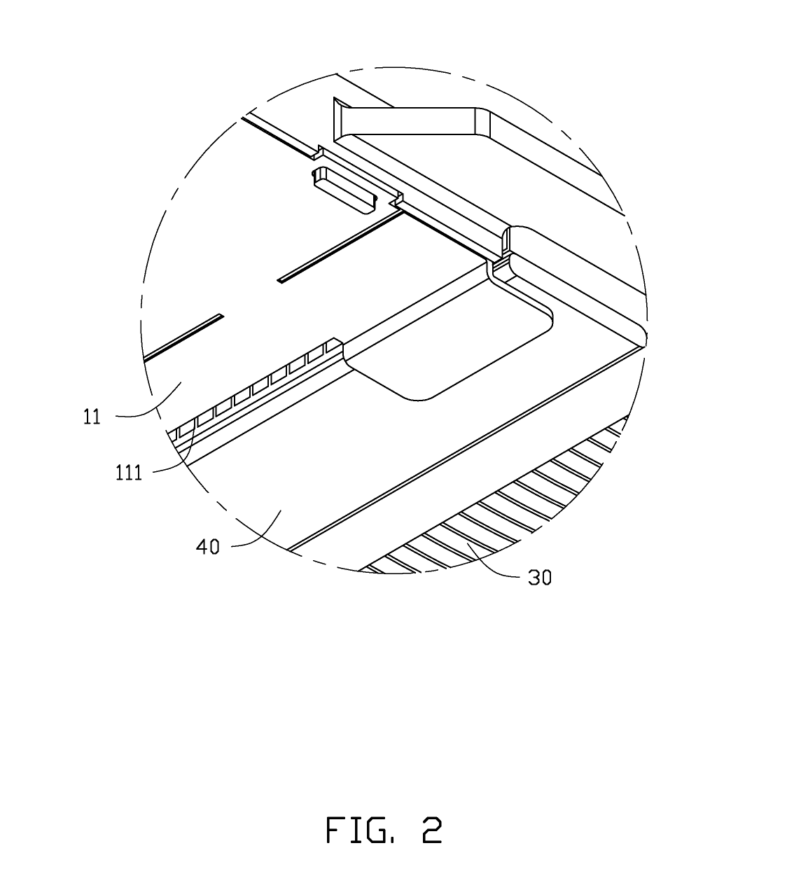

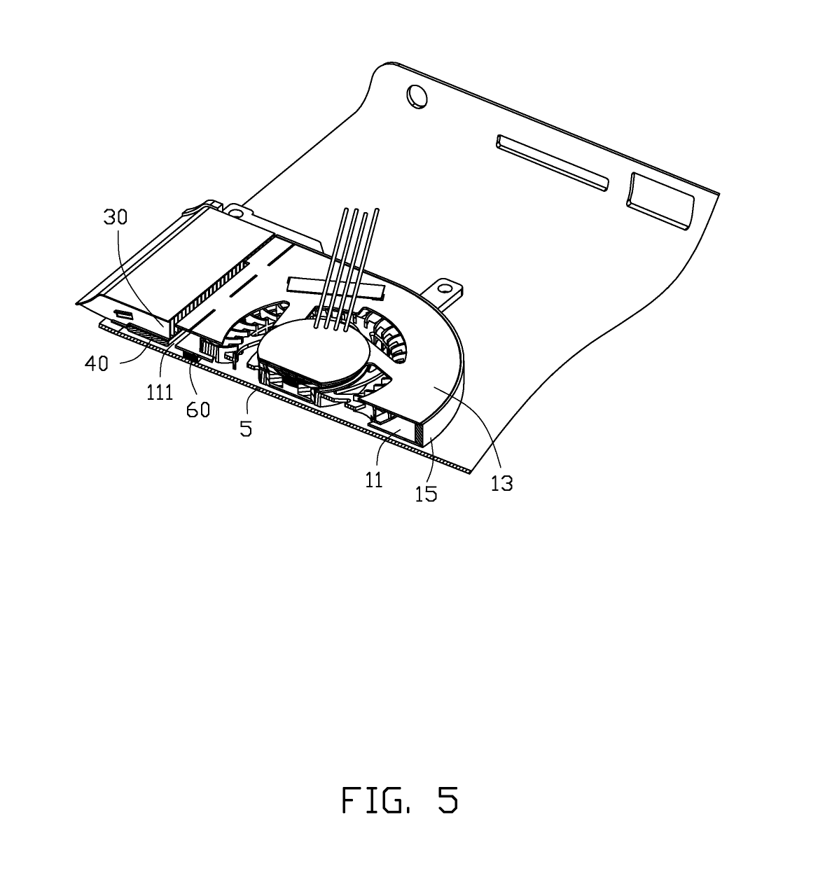

FIGS. 2 and 5 show that the installation box 10 includes a first installation plate 11, a second installation plate 13, and a connecting plate 15 connected to the first installation plate 11 and the second installation plate 13. In one embodiment, the first installation plate 11 is substantially parallel to the second installation plate 13. The fan 20 is secured between the first installation plate 11 and the second installation plate 13. The first installation plate 11 defines an elongated cutout 111 in communication with an airflow passage of the fan 20. A width of the cutout 111 is in a range from about 0.8 mm to about 3 mm, and a length of the cutout 111 is about 10 mm. In one embodiment, the width of the cutout 111 is about 1 mm.

The plurality of fins 30 is secured to the installation box 10 and is located near the fan 20. One end of the pipe 40 is attached to the plurality of fins 30, and the other end of the pipe 40 is attached to the heat sink 50. The heat sink 50 dissipates heat generated by one of heat generating components, such as CPU.

The baffle piece 60 is secured to the first installation plate 11 and arranged at two adjacent edges of the cutout 111, to prevent airflow from the fan 20 from back-flow. In one embodiment, the baffle piece 60 is substantially L-shaped and made of sponge. A width of the baffle piece 60 is about 2 mm to about 4 mm and a length of the baffle piece 60 is changeable according to the length of the cutout 111. In one embodiment, the width of the baffle piece 60 is about 3 mm, and the length of the baffle piece 60 is longer than the length of the cutout 111.

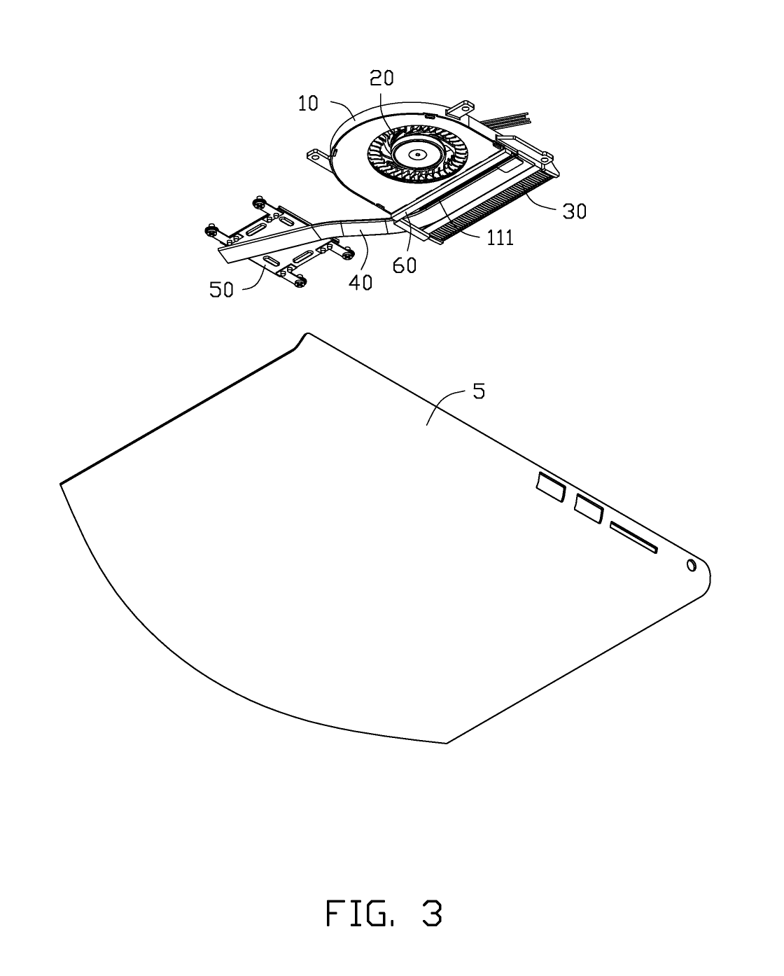

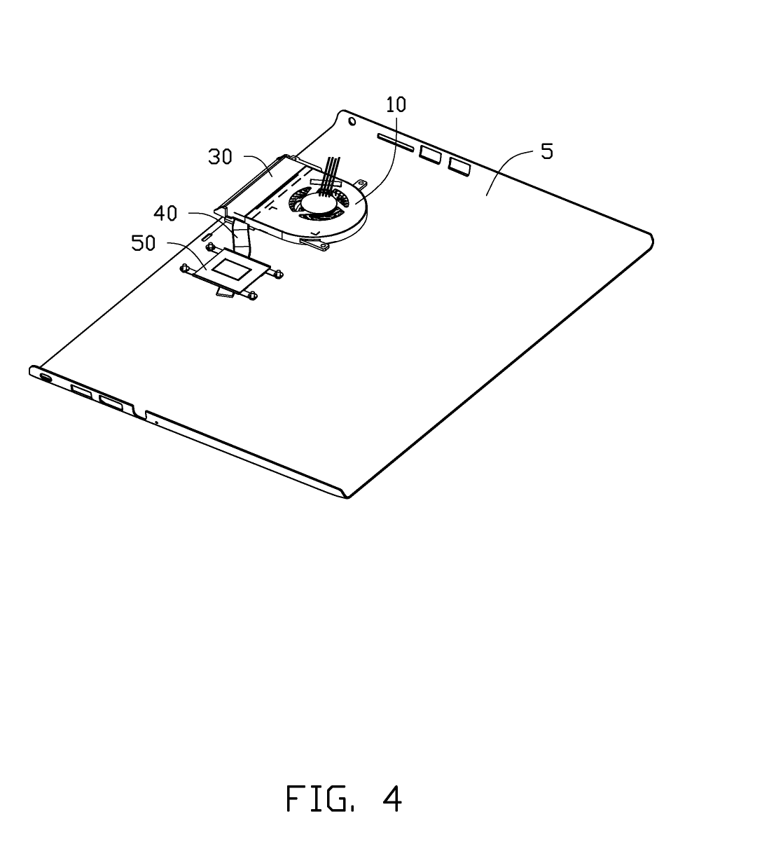

FIGS. 3-5 illustrate an assembled view of the electronic device in accordance with an embodiment. In assembly, the heat dissipating module 80 is attached to the bottom enclosure 5, and the baffle piece 60 is located between the bottom enclosure 5 and the first installation plate 11. A thickness of the baffle piece 60 is substantially equal to a distance between the first installation plate 11 and the bottom enclosure 5.

In use, the fan 20 generates an airflow along a first direction through the plurality of fins 30 to dissipate heat generated by the heat generating component, and along second direction through the cutout 111 to dissipate heat generated by the bottom enclosure 5. The first direction is substantially perpendicular to the second direction.

The heat dissipating module 80 not only dissipates heat from the heat generating component, but also dissipates heat from the bottom enclosure 5.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device comprising:
a bottom enclosure; and
a heat dissipating module comprising:
an installation box attached to the bottom enclosure and defining a cutout;
a fan received in the installation box; and
a plurality of fins secured to the installation box and closed to the fan;
wherein the cutout is located between the fan and the plurality of fins, an airflow directed by the fan is guided along a first direction by the plurality of fins to dissipate heat generated from a heat generating component that is thermally connected to the plurality of fins, and along a second direction through the cutout to dissipate heat generated from the bottom enclosure; and the second direction is substantially perpendicular to the first direction.

2. The electronic device of claim 1, further comprising a baffle piece, wherein the baffle piece is secured to the installation box and arranged at two adjacent edges of the cutout, to prevent the airflow backflow.

3. The electronic device of claim 2, wherein the installation box comprises a first installation plate, and the baffle piece is located between the bottom enclosure and the first installation plate.

4. The electronic device of claim 3, wherein the installation box further comprises a second installation plate, and the fan is received between the first installation plate and the second installation plate.

5. The electronic device of claim 2, wherein the baffle piece is made of sponge.

6. The electronic device of claim 4, wherein a width of the baffle piece is about 2 mm to about 4 mm.

7. The electronic device of claim 6, wherein the width of the baffle piece is about 3 mm.

8. The electronic device of claim 2, wherein a length of the baffle plat is greater than a length of the cutout.

9. The electronic device of claim 8, wherein a width of the cutout is about 0.8 mm to about 3 mm.

10. The electronic device of claim 9, wherein the width of the cutout is about 1 mm.

11. A heat dissipating module comprising:
an installation box defining a cutout;
a fan received in the installation box;
a plurality of fins secured to the installation box and closed to the fan,
wherein the cutout is located between the fan and the plurality of fins, airflow generated by the fan is guided along a first direction to configure to dissipate heat generated by a heat generating component, and along a second direction to configure to dissipate heat generated by a bottom enclosure; and the second direction is substantially perpendicular to the first direction.

12. The heat dissipating module of claim 11, further comprising a baffle piece, wherein the baffle piece is secured between the installation box and arranged at two adjacent edges of the cutout, to prevent the airflow backflow.

13. The heat dissipating module of claim 12, wherein the installation box comprises a first installation plate, and the baffle piece is located between the bottom enclosure and the first installation plate.

14. The heat dissipating module of claim 13, wherein the installation box further comprises a second installation plate, and the fan is received between the first installation plate and the second installation plate.

15. The heat dissipating module of claim 12, wherein the baffle piece is made of sponge.

16. The heat dissipating module of claim 14, wherein a width of the baffle piece is about 2 mm to about 4 mm.

17. The heat dissipating module of claim 16, wherein the width of the baffle piece is about 3 mm.

18. The heat dissipating module of claim 12, wherein a length of the baffle plat is greater than a length of the cutout.

19. The heat dissipating module of claim 18, wherein a width of the cutout is about 0.8 mm to about 3 mm.

20. The heat dissipating module of claim 19, wherein the width of the cutout is about 1 mm.
